(19) United States
(12) Patent Application Publication
(10) Pub. No.: US 2016/0013411 A1
(43) Pub. Date: Jan. 14, 2016

(54) METHOD OF MANUFACTURING MULTI-LAYERED THIN FILMS, MULTI-LAYERED THIN FILMS FORMED BY THE SAME, METHOD OF MANUFACTURING ORGANIC THIN FILM TRANSISTOR INCLUDING THE SAME, AND ORGANIC THIN FILM TRANSISTOR MANUFACTURED BY THE SAME

(71) Applicant: KOREA INSTITUTE OF SCIENCE AND TECHNOLOGY, Seoul (KR)

(72) Inventors: Jung Ah LIM, Seoul (KR); Yong-Won SONG, Seoul (KR); Su Jin LEE, Seoul (KR); Won-Kook CHOI, Seoul (KR)

(21) Appl. No.: 14/512,154

(22) Filed: Oct. 10, 2014

(30) Foreign Application Priority Data
Jul. 14, 2014 (KR) 10-2014-0088232

(51) Int. Cl. H01L 51/00; H01L 51/05

(52) U.S. Cl. CPC H01L 51/0004; H01L 51/0545

(57) ABSTRACT

Provided are a method of manufacturing multi-layered thin films, multi-layered thin films formed by the same, a method of manufacturing an organic thin film transistor including the same, and an organic thin film transistor manufactured by the same. The method of manufacturing multi-layered thin films includes: preparing a substrate; printing a blend solution including an organic semiconductor, an insulating polymer, and a solvent on the substrate; and simultaneously forming an insulating polymer thin film and an organic semiconductor thin film on the insulating polymer thin film by using a vertical phase separation phenomenon of the organic semiconductor and the insulating polymer, in which according to contents of the organic semiconductor and the insulating polymer in the blend solution and a printing speed of the blend solution, a width of the organic semiconductor thin film, and a thickness of the insulating polymer thin film are controlled.

### CROSS-REFERENCE TO RELATED APPLICATION

This application claims priority to and the benefit of Korean Patent Application No. 10-2014-0088232 filed in the Korean Intellectual Property Office on Jul. 14, 2014, the entire contents of which are incorporated herein by reference.

### BACKGROUND OF THE INVENTION

(a) Field of the Invention

The present invention relates to a method of manufacturing multi-layered thin films, multi-layered thin films formed by the same, a method of manufacturing an organic thin film transistor including the same, and an organic thin film transistor manufactured by the same.

(b) Description of the Related Art

A solution process in which a thin film is formed on a substrate by dissolving an organic semiconductor and the like in a solvent has been frequently used when manufacturing an organic thin film transistor. When multi-layered thin films constituted by a dielectric layer, an organic semiconductor layer, and a protective layer are manufactured by the solution process, there may be a problem in that a solvent damages a previously formed lower layer in a subsequent process.

In order to more effectively implement the solution process, researches to implement the multi-layered thin films through one coating process have been conducted. Further, in order to lower manufacturing cost of the multi-layered thin films, the demand for methods using a small amount of an expensive organic semiconductor has been continuous.

In order to solve the demand, methods which can improve performance of the organic thin film transistor by using phase separation of an organic semiconductor and an insulating polymer or manufacture an organic semiconductor thin film and an insulating polymer thin film through one process have recently been proposed.

In the case of the invention of Korean Patent Application No. 10-2008-90070 filed on Sep. 11, 2008, a method of manufacturing multi-layered thin films in which an organic semiconductor thin film is simultaneously formed on an insulating polymer thin film by using a coating method was proposed, and a method of manufacturing an organic thin film transistor including the same was also proposed.

The meaning of the patent is that, since the multi-layered thin films of the above structure are manufactured to make a thickness of the insulating polymer thin film thin, the organic thin film transistor using the same can be driven with low power and has excellent transistor performance with a small amount of the organic semiconductor to reduce costs of the organic semiconductor.

Similarly, in an article by Dr. Wi Hyoung Lee disclosed in Advanced Materials in 2009, vertical phase separation in which an organic semiconductor thin film is positioned on an insulating polymer thin film through a spin coating method was proposed, and a solvent annealing process for more perfect vertical phase separation was also proposed.

The meaning of the 2009 article was to improve interface roughness of the organic semiconductor thin film and the insulating polymer thin film and improve a coating characteristic of the organic semiconductor to finally improve an element characteristic of the organic thin film transistor.

However, in order to apply the organic thin film transistor to an electronic circuit, it is necessary to form an organic semiconductor thin film pattern to control a width thereof, but no cases of simultaneously printing patterns of the organic semiconductor thin film and the insulating polymer thin film by using a printing process, rather than the coating method in the patent application and the 2009 article, have yet been reported.

Meanwhile, in an article by Dr. Song Yun Cho of Korea Research Institute of Chemical Technology disclosed in J. Mater. Chem. C in 2012, vertical phase separation of a blend solution of an organic semiconductor and an insulating polymer by using an inkjet printing method was proposed. The meaning of the 2013 article is to improve alignment of the organic semiconductor and uniformity of the thin films, as a case of printing the blend solution of the organic semiconductor and the insulating polymer by using one of printing methods.

However, even in the 2013 article, the blend solution of the organic semiconductor and the insulating polymer has a vertical phase separation characteristic, but there is a limit in that a lower insulating polymer thin film does not ensure the characteristic as the insulating film and the width of the organic semiconductor thin film on the printed pattern is not controlled.

The above information disclosed in this Background section is only for enhancement of understanding of the background of the invention and therefore it may contain information that does not form the prior art that is already known in this country to a person of ordinary skill in the art.

### SUMMARY OF THE INVENTION

Accordingly, the inventors developed a method of manufacturing multi-layered thin films that uses vertical phase separation of a blend solution of an organic semiconductor and an insulating polymer and can simultaneously form an organic semiconductor thin film and an insulating polymer thin film by a printing method.

In detail, according to an exemplary embodiment of the present invention, the organic semiconductor thin film is positioned at a center of the printed pattern, and a width of the organic semiconductor thin film on the printed pattern may be controlled.

An exemplary embodiment of the present invention provides a method of manufacturing multi-layered thin films, including: preparing a substrate; printing a blend solution including an organic semiconductor, an insulating polymer, and a solvent on the substrate; and simultaneously forming an insulating polymer thin film and an organic semiconductor thin film on the insulating polymer thin film by using a vertical phase separation phenomenon of the organic semiconductor and the insulating polymer, in which according to contents of the organic semiconductor and the insulating polymer in the blend solution and a printing speed of the blend solution, a width of the multi-layered thin film pattern, a width of the organic semiconductor thin film, and a thickness of the insulating polymer thin film are controlled.

The insulating polymer may be an amorphous polymer.

The insulating polymer may be a polyacrylate-based polymer, a polyphenol-based polymer, a polyimide-based polymer, a polyvinyl alcohol-based polymer, or a combination thereof.

The organic semiconductor may be a thiophene-based compound, a thiazine-based compound, a polyacene-based derivative, a polyaniline-based compound, a polyacetylene-based compound, or a combination thereof.

The solvent may be an organic chlorine-based compound, an organic fluorine-based compound, a hydrocarbon-based compound, an alcohol-based compound, a benzene-based compound, or a combination thereof. In detail, the solvent may be 1,2,4-trichlorobenzene (TCB).

The content of the organic semiconductor and the insulating polymer in the blend solution may be a weight ratio of the organic semiconductor to the insulating polymer of 2:1 to 1:8. In detail, the content may be 2:1 to 1:1, 1:4, 1:6, and 1:8.

A width of the organic semiconductor thin film may be 1 to 200 μm, and in detail, 1 to 10 μm.

The content of the organic semiconductor and the insulating polymer in the blend solution may be 1 to 15 wt %.

The thickness of the insulating polymer thin film may be 10 to 1000 nm, in detail, 50 to 600 nm.

The organic semiconductor thin film may be positioned at a center of the printed pattern.

The shape of the formed insulating polymer thin film and organic semiconductor thin film may be linear.

The substrate may have larger surface energy than surface energy of the insulating polymer, and for example, may be a silicon substrate or a polymer substrate.

In the printing of the blending solution including the organic semiconductor, the insulating polymer, and the solvent on the substrate, the printing method may be at least one method of inkjet printing, roll to roll printing, or screen printing.

The printing speed may be 10 to 2000 μm/s.

The printing method may use a microfluidic dispenser.

Another exemplary embodiment of the present invention provides multi-layered thin films wherein a blend solution including an organic semiconductor, an insulating polymer, and a solvent is printed to form an organic semiconductor layer on the insulating polymer layer according to any one of the aforementioned methods of manufacturing the multilayered thin films.

Yet another exemplary embodiment of the present invention provides a method of manufacturing an organic thin film transistor, including: preparing a substrate; preparing a gate electrode on the substrate; printing a blend solution including an organic semiconductor, an insulating polymer, and a solvent according to any one of the aforementioned methods of manufacturing the multilayered thin films; and forming a source electrode and a drain electrode on the printed pattern.

In the forming of the source electrode and the drain electrode on the printed pattern, the source electrode and the drain electrode may be formed by printing.

Still another exemplary embodiment of the present invention provides an organic thin film transistor including: a substrate to which a gate electrode is connected; a first dielectric layer formed on the substrate; a second dielectric layer formed on the first dielectric layer; an organic semiconductor thin film formed on the second dielectric layer; and source and drain electrodes connected to the organic semiconductor thin film manufactured by the aforementioned method of manufacturing the organic thin film transistor.

According to the exemplary embodiment of the present invention, it is possible to provide a method of manufacturing the multi-layered thin films that can use vertical phase separation of the blend solution of the organic semiconductor and the insulating polymer and simultaneously form the organic semiconductor thin film and the insulating polymer thin film by a printing method.

In detail, according to the exemplary embodiment of the present invention, the width of the multi-layered thin film pattern, the width of the organic semiconductor thin film, and the thickness of the insulating polymer thin film may be controlled. Further, the organic semiconductor thin film may be positioned at the center of the printed pattern.

Further, the present invention provides multi-layered thin films formed by the same, a method of manufacturing an organic thin film transistor including the same, and an organic thin film transistor manufactured by the same.

### BRIEF DESCRIPTION OF THE DRAWINGS

FIG. 1 illustrates a form of manufacturing multi-layered thin films according to an exemplary embodiment of the present invention.

FIG. 2A is a microphotograph of multi-layered thin films manufactured according to an exemplary embodiment of the present invention. (Left: original image/Right: polarized image)

FIG. 2B shows a thickness profile after selectively removing only an organic semiconductor thin film, in the multi-layered thin films manufactured according to the exemplary embodiment of the present invention.

FIG. 2C is a microphotograph of multi-layered thin films manufactured according to another exemplary embodiment of the present invention. (Left: original image/Right: polarized image)

FIG. 2D shows a thickness profile after selectively removing only an organic thin film, in the multi-layered thin films manufactured according to another exemplary embodiment of the present invention.

FIG. 3A shows XPS data of multi-layered thin films manufactured according to an exemplary embodiment of the present invention.

FIG. 3B XPS data observed after selectively removing only an organic semiconductor thin film, in the multi-layered thin films manufactured according to the exemplary embodiment of the present invention.

FIG. 3C SEM-EDX data for a central portion, in the multi-layered thin films manufactured according to the exemplary embodiment of the present invention.

FIG. 3D SEM-EDX data for an edge portion, in the multi-layered thin films manufactured according to the exemplary embodiment of the present invention.

FIG. 4 is a diagram of measurement of an aspect in which a width of an organic semiconductor thin film is changed according to a change in a weight ratio of an organic semiconductor for an insulating polymer in a blend solution, in the multi-layered thin films manufactured according to the exemplary embodiment of the present invention.

FIG. 5A illustrates an element structure of an organic thin film transistor manufactured according to an exemplary embodiment of the present invention.

A right image of FIG. 5A illustrates an organic thin film transistor manufactured according to an exemplary embodiment of the present invention.

FIG. 5B is a diagram illustrating an output characteristic of the organic thin film transistor manufactured according to an exemplary embodiment of the present invention.

FIG. 5C is a diagram illustrating a transfer characteristic of the organic thin film transistor manufactured according to an exemplary embodiment of the present invention.

FIG. 6 illustrates a change in thickness and a surface profile of an insulating polymer thin film according to a change in total concentration of an organic semiconductor and an insulating polymer in a blend solution, in the multi-layered thin films manufactured according to an exemplary embodiment of the present invention.

FIG. 7 illustrates a surface profile and a change in thickness of the insulating polymer thin film according to a change in printing speed, during printing for forming the multi-layered thin films according to an exemplary embodiment of the present invention.

### DETAILED DESCRIPTION OF THE EMBODIMENTS

Hereinafter, exemplary embodiments of the present invention will be described in detail. However, the exemplary embodiments are exemplary, and the present invention is not limited thereto and may be defined by the scope of claims to be described below.

An exemplary embodiment of the present invention provides a method of manufacturing multi-layered thin films, including: preparing a substrate; printing a blend solution including an organic semiconductor, an insulating polymer, and a solvent on the substrate; and simultaneously forming an insulating polymer thin film and an organic semiconductor thin film on the insulating polymer thin film by using a vertical phase separation phenomenon of the organic semiconductor and the insulating polymer, in which, according to contents of the organic semiconductor and the insulating polymer in the blend solution and/or a printing speed of the blend solution, a width of the multi-layered thin film pattern, a width of the organic semiconductor thin film, and a thickness of the insulating polymer thin film are controlled.

With respect to the vertical phase separation phenomenon, methods of causing phase separation in the blend solution include lateral phase separation and vertical phase separation. Among the methods, the vertical phase separation is a method that may be performed by controlling a difference in surface energy, a mutual affinity between materials, and an evaporation behavior of the solvent.

The insulating polymer, as an insulating polymer having larger surface energy than the organic semiconductor, may be an amorphous polymer.

For example, the insulating polymer may be a polyacrylate-based polymer, a polyphenol-based polymer, a polyimide-based polymer, a polyvinyl alcohol-based polymer, or a combination thereof, which may be dissolved in an organic solvent.

In more detail, as the insulating polymer, polymers such as polymethyl methacrylate, polyimide, polyvinyl phenol, polyvinyl alcohol, and polystyrene may be used.

Further, the organic semiconductor, as an organic semiconductor having smaller surface energy than the insulating polymer, may use various organic semiconductors in which a solution process is possible.

For example, the organic semiconductor may be a thiophene-based compound, a thiazine-based compound, a polyacene-based derivative, a polyaniline-based compound, a polyacetylene-based compound, or a combination thereof.

A difference in surface energy between the organic semiconductor and the insulating polymer is not limited if vertical phase separation of the organic semiconductor and the insulating polymer is caused. In detail, in the case of using a combination in which the difference in surface energy is 2.0 mJm⁻² or more, the vertical phase separation of the organic semiconductor and the insulating polymer is facilitated to reduce a processing time.

The solvent, as a material which may dissolve the organic semiconductor and the insulating polymer, may be an organic chlorine-based compound, an organic fluorine-based compound, a hydrocarbon-based compound, an alcohol-based compound, a benzene-based compound, or a combination thereof.

For example, 1,2,4-trichlorobenzene (TCB) may be used as the solvent. In this case, due to a characteristic of TCB having a relatively high boiling point of 214° C. and a low evaporation speed, sufficient time may be provided for the vertical phase separation of the organic semiconductor and the insulating polymer.

In the printing of the blend solution including the organic semiconductor, the insulating polymer, and the solvent on the substrate, the content of the organic semiconductor and the insulating polymer in the blend solution may be 2:1 to 1:8 as a weight ratio of the organic semiconductor to the insulating polymer. In detail, the content may be 2:1 to 1:1, 1:4, 1:6, or 1:8.

Within the range, as the weight ratio is increased, a width of the organic semiconductor thin film compared to a width of the multi-layered thin film printed pattern may be increased. In detail, when the weight ratio is 2:1, the width of the organic semiconductor thin film may be 90% of the width of the multi-layered thin film printed pattern.

The width of the organic semiconductor thin film may be 1 μm to 200 μm, and in detail, 1 μm to 10 μm.

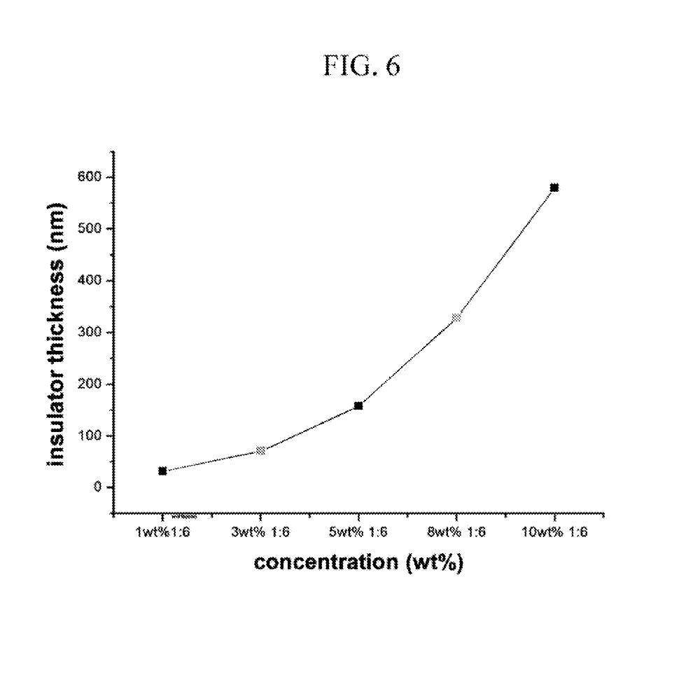

FIG. 6 illustrates a change in thickness and a surface profile of an insulating polymer thin film according to a change in total concentration of an organic semiconductor and an insulating polymer in a blend solution, in the multi-layered thin film pattern manufactured according to an exemplary embodiment of the present invention.

In order to apply the multi-layered thin films according to the exemplary embodiment to a transistor element, it is important to ensure that the insulating polymer thin film has a predetermined thickness or more. The reason is that when the insulating polymer thin film is very thin, an insulating characteristic is not ensured, and as a result, even though an electric field is applied for element driving, the element is not driven.

In this case, the total concentration of the organic semiconductor and the insulating polymer in the blend solution may be 1 to 15 wt %. Within the range, as the weight percentage is increased, the thickness of the insulating polymer thin film may be effectively controlled. In this case, the width and the thickness of the organic semiconductor thin film may not be changed.

The thickness of the insulating polymer thin film may be 10 to 1000 nm, and in detail, 50 to 600 nm.

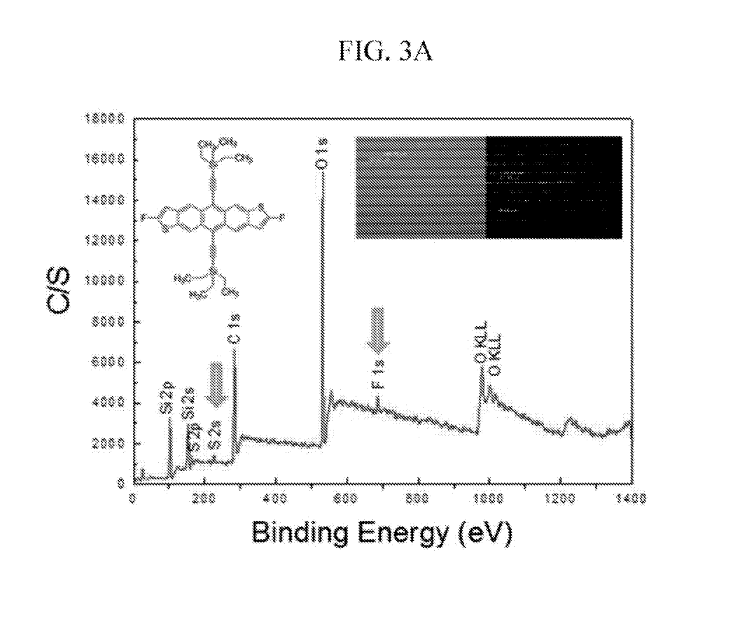

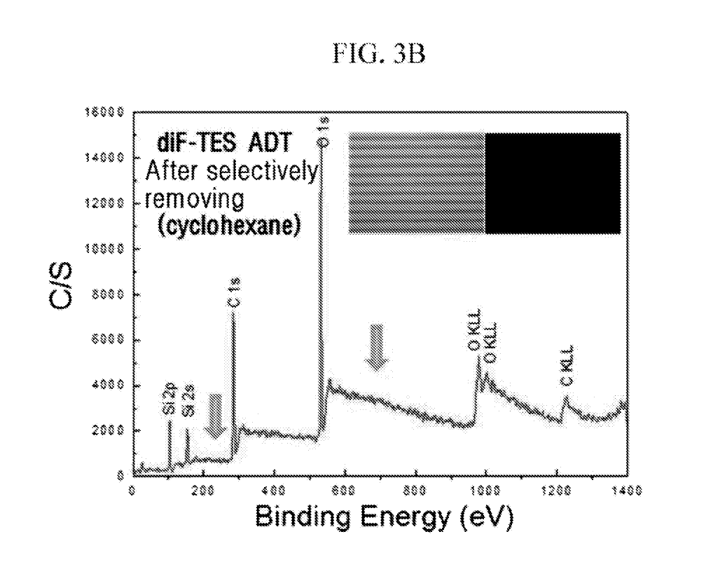

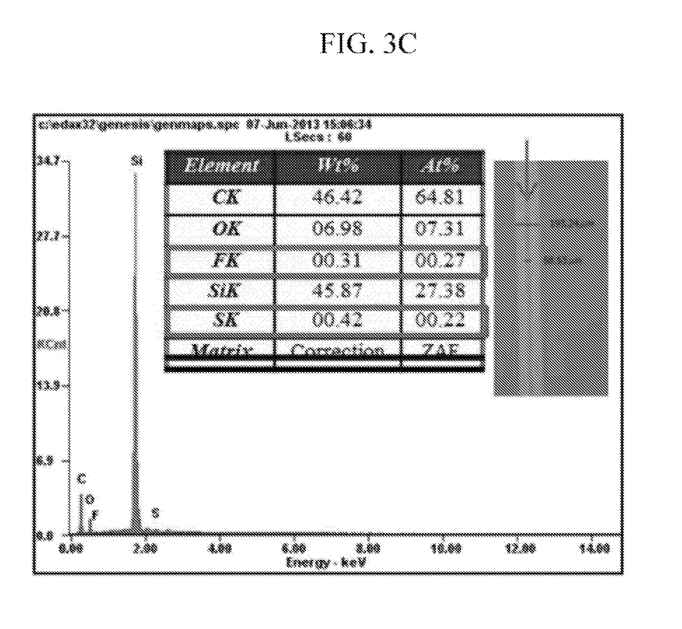

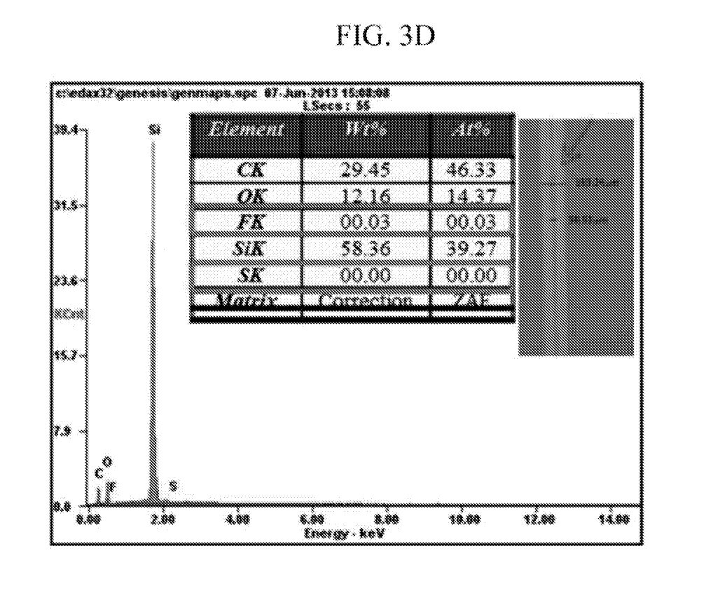

The organic semiconductor thin film may be positioned at a center of the printed pattern. However, the meaning of the center is not necessarily limited to dead center. That is, as illustrated in FIGS. 3 (c) and (d), this means that the organic semiconductor thin film is present not at the edge of the printed pattern but at the central portion.

A shape of the formed insulating polymer thin film and organic semiconductor thin film may be linear. However, the shape is not limited thereto, and patterns having various shapes may be implemented.

The substrate may have larger surface energy than the surface energy of the insulating polymer. For example, the substrate may be a silicon substrate and/or a polymer substrate.

In this case, the insulating polymer thin film having relatively large surface energy is formed at the bottom of the multi-layered thin films, and the organic semiconductor thin film having relatively small surface energy may be formed at the top of the multi-layered thin films.

In detail, the substrate may be a general Si substrate used as a gate electrode, and as another example, the substrate may be a substrate in which thermally grown silicon dioxide which serves as a dielectric layer is formed on the surface of the silicon substrate.

In the printing of the blend solution including the organic semiconductor, the insulating polymer, and the solvent on the substrate, the printing method may be at least one of inkjet printing, roll to roll printing, and screen printing.

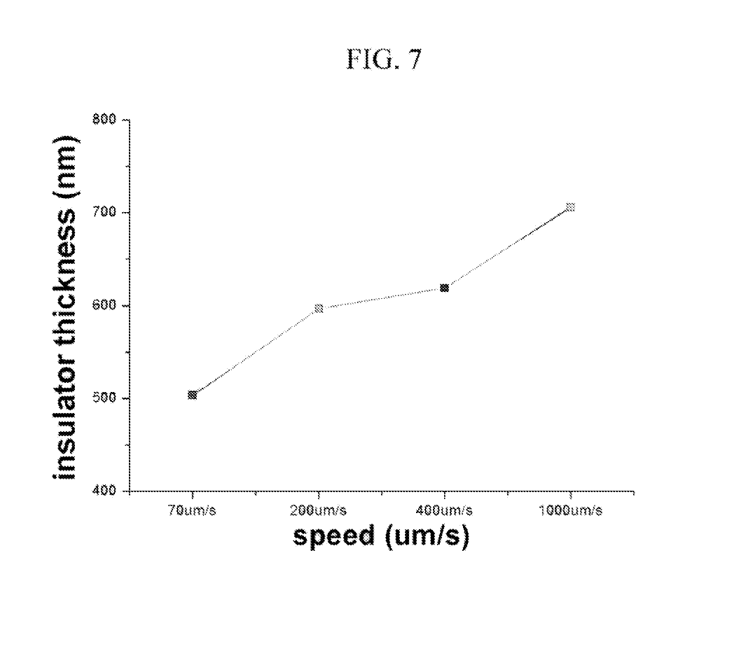

FIG. 7 illustrates a surface profile and a change in thickness of the insulating polymer thin film according to a change in printing speed, during printing for forming the multi-layered thin film patterns according to an exemplary embodiment of the present invention.

The printing speed may be 10 to 2000 μm/s. In the case of satisfying the range, the width of the printed pattern, the width of the organic semiconductor thin film, and the thickness of the insulating polymer thin film may be effectively controlled.

In detail, as the printing speed is increased within the range, the width of the printed pattern may be decreased, and accordingly, the width of the organic semiconductor thin film may also be decreased. Further, as the printing speed is increased, the thickness of the insulating polymer thin film may be increased.

The printing method may use a microfluidic dispenser. The microfluidic dispenser may provide a method of forming a pattern by contacting droplets on the substrate, after controlling a meniscus generated in nozzles by controlling deformation of a piezoelectric element.

Another exemplary embodiment of the present invention provides multi-layered thin films in which an organic semiconductor layer is formed on an insulating polymer layer by printing a blend solution including an organic semiconductor, an insulating polymer, and a solvent according to any one of the aforementioned methods of manufacturing the multi-layered thin films.

Yet another exemplary embodiment of the present invention provides a method of manufacturing an organic thin film transistor including: preparing a substrate; preparing a gate electrode on the substrate; printing a blend solution including an organic semiconductor, an insulating polymer, and a solvent according to any one of the aforementioned methods of manufacturing the multi-layered thin films; and forming a source electrode and a drain electrode on the printed pattern.

The forming of the source electrode and the drain electrode on the printed pattern may be performed by printing.

Still another exemplary embodiment of the present invention provides an organic thin film transistor including: a substrate to which a gate electrode is connected; a first dielectric layer formed on the substrate; a second dielectric layer formed on the first dielectric layer; an organic semiconductor thin film formed on the second dielectric layer; and source and drain electrodes connected to the organic semiconductor thin film, and manufactured according to the aforementioned method of manufacturing the organic thin film transistor.

Hereinafter, examples and experimental examples of the present invention are disclosed. However, the following examples are just preferable examples of the present invention, and the present invention is not limited to the following examples.

### Example 1

A blend solution was manufactured by setting a weight ratio of an organic semiconductor to an insulating polymer to 1:1 and using 1,2,4-trichlorobenzene (TCB) (purchased from Sigma-Aldrich) as a solvent.

The insulating polymer used was polymethyl methacrylate (PMMA) (purchased from Sigma-Aldrich), and the organic semiconductor used was 2,8-difluoro-5,11-bis(triethylsilylethynyl)anthradithiophene (diF-TES ADT) (purchased from Lumtec).

A total concentration of polymethyl methacrylate and diF-TES ADT in the blend solution was 10 wt %.

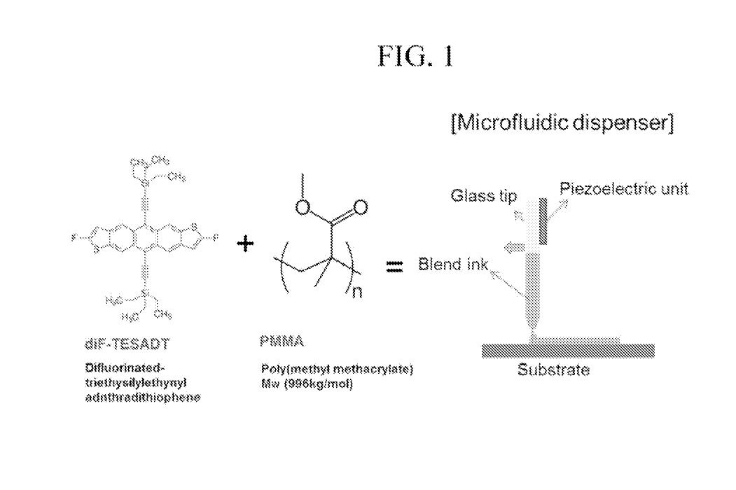

The multi-layered thin films were manufactured by printing the manufactured blend solution on a 300 nm SiO₂ substrate (LG Siltron Inc., silicon wafer (polished-prime)) by using a microfluidic dispenser. This is illustrated in FIG. 1.

### Examples 2 to 4

In Example 1, except that the weight ratio is changed to 1:4 (Example 2), 1:6 (Example 3), and 2:1 (Example 4), the multi-layered thin films were manufactured by the same method as Example 1.

### Examples 5 to 8

In Example 3, except that the total concentration is changed to 1 (Example 5), 3 (Example 6), 5 (Example 7), and 8 (Example 8) wt %, the multi-layered thin films were manufactured by the same method as Example 3.

### Example 9

In Example 2, except that the total concentration is changed to 8 wt %, the multi-layered thin films were manufactured by the same method as Example 2.

### Experimental Examples 1 and 2

### Verification of Position of Organic Semiconductor Thin Film in Multi-Layered Thin Films and Verification of Control Probability of Thickness of Each Thin Film of Multi-Layered Thin Films

### Experimental Example 1

### Observation of Printing Form of Multi-Layered Thin Films

The multi-layered thin films manufactured in Examples 1 and 2 were observed by using polarization of an optical microscope (BX51, purchased from Olympus).

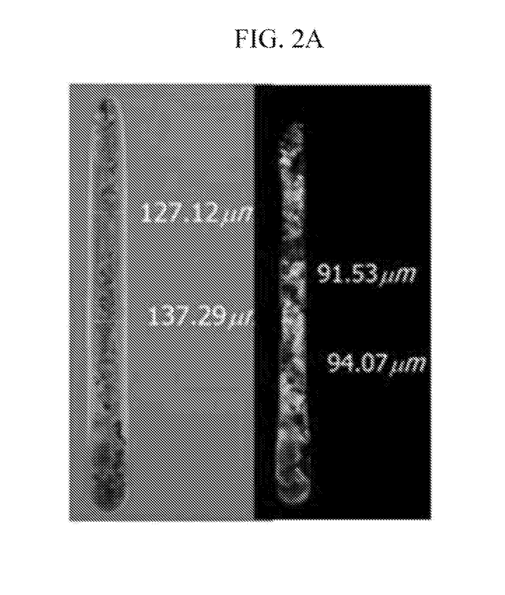

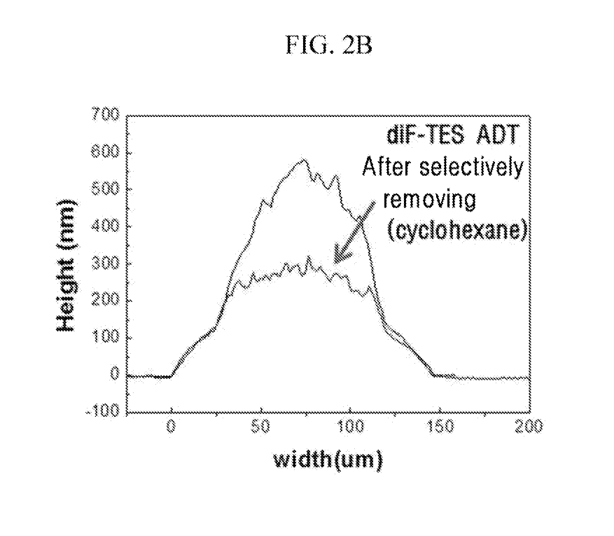

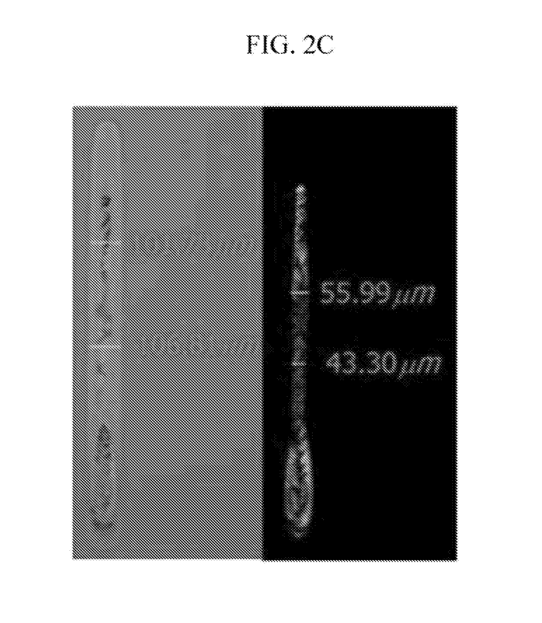

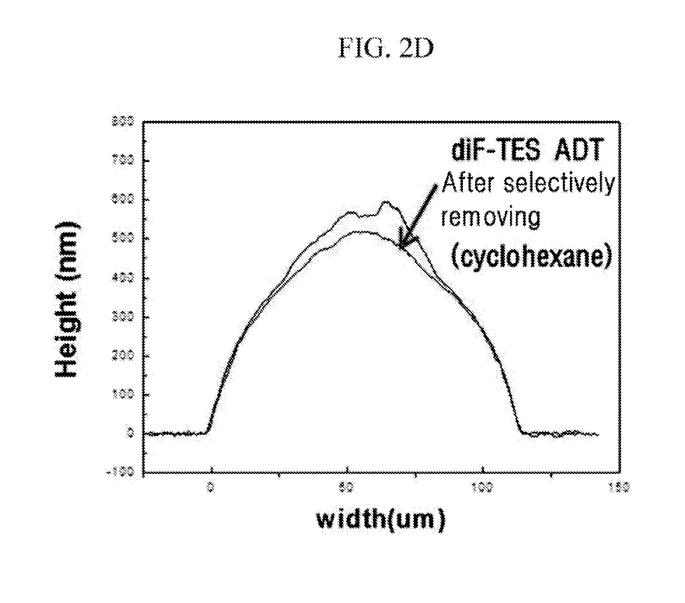

The forms are illustrated in FIGS. 2A and 2C, respectively. In each drawing, a left image is an original image, and a right image is a polarized image.

As illustrated in FIGS. 2A and 2C, regardless of the weight ratio, it can be seen that the organic semiconductor thin film in the multi-layered thin films manufactured according to the exemplary embodiment of the present invention is a linear crystal and is positioned at the center of the printed pattern.

### Experimental Example 2

### Observation of Thickness Profile of Multi-Layered Thin Films

The position of the organic semiconductor thin film in the multi-layered thin films was determined, and in order to compare a thickness of each layer according to the weight ratio, the multi-layered thin films manufactured in Examples 1 and 2 were soaked in cyclohexane and then only a diF-TES ADT thin film was selectively removed.

A thickness profile of the multi-layered thin films was measured by using a film measuring device. FIGS. 2B and 2D show thickness profiles after selectively removing only the diF-TES ADT thin film in the multi-layered thin films manufactured according to each of Examples 1 and 2 of the present invention, respectively.

In FIGS. 2B and 2D, it can be seen that regardless of the weight ratio, the organic semiconductor thin film is positioned on the top of the multi-layered thin films manufactured according to the exemplary embodiment of the present invention.

Further, by comparing FIGS. 2B and 2D, it can be seen that the thicknesses of the top and bottom thin films in the multi-layered thin films may be controlled according to the weight ratio.

In detail, referring to FIG. 2B, the thicknesses of the organic semiconductor thin film and the insulating polymer thin film in the multi-layered thin films manufactured in Example 1 were 250 nm and 300 nm, respectively. On the other hand, it can be seen that the thicknesses of the organic semiconductor thin film and the insulating polymer thin film in the multi-layered thin films manufactured in Example 2 were 50 nm and 500 nm, respectively.

Accordingly, it can be seen that as the weight ratio of the organic semiconductor to the insulating polymer in the blend solution is decreased, the thickness of the organic semiconductor thin film in the manufactured multi-layered thin films is decreased.

### Experimental Examples 3 and 4

### Verification of Vertical Phase Separation

### Experimental Example 3

### Analysis of XPS Data in Multi-Layered Thin Films

With respect to the multi-layered thin films manufactured in Example 2, a nondestructive surface analysis was performed by using XPS equipment (PHI 5000 VersaProbe, purchased from Ulvac-PHI)

In detail, background pressure was set as 6.7×10⁻⁸ Pa, 1486.6 eV was applied to an aluminum (Al) Kα ray source, and power of 25 W and a voltage of 15 kV were applied to an anode. In this case, a spot size was set as 100 μm×100 μm.

In FIG. 3A showing a result of the analysis, F and S peaks were verified. Herein, all of the F and S peaks are peaks shown by a molecular structure of diF-TES ADT.

Meanwhile, in order to verify whether the vertical phase separation occurred well, in the same manner as Experimental Example 2, an XPS analysis was performed after selectively removing only the diF-TES ADT in the multi-layered thin films manufactured in Example 2.

The result is illustrated in FIG. 3B, and it can be verified that the F and S peaks were not obtained.

By comparing FIGS. 3A and 3B, it can be verified that the organic semiconductor was not present in the bottom thin film of the multi-layered thin films. This verifies that the vertical phase separation of the organic semiconductor and the insulating polymer occurred well.

Accordingly, it can be seen that regardless of the weight ratio, the insulating polymer thin film is positioned at the bottom of the multi-layered thin films manufactured according to the exemplary embodiment of the present invention, an organic semiconductor material is not included in the insulating polymer thin film, and the vertical phase separation may occur well.

### Experimental Example 4

### Analysis of SEMEDX Data in Multi-Layered Thin Films

The data obtained by measuring SEMEDX at a central portion and an edge portion of the printed pattern of the multi-layered thin films manufactured in Example 9 are illustrated in FIGS. 3C and 3D, respectively.

As illustrated in FIG. 3C, F and S were detected at the central portion of the multi-layered thin films manufactured in Example 9. As described above, the detection of F and S orbitals is performed by the molecular structure of diF-TES ADT.

On the other hand, as illustrated in FIG. 3D, F and S were not detected at the edge portion of the multi-layered thin films manufactured in Example 9.

By comparing FIGS. 3C and 3D, it can be verified that the organic semiconductor thin film is not present at the edge portion of the multi-layered thin films manufactured in Example 9.

Accordingly, it can be seen that the organic semiconductor thin film in the multi-layered thin films is not positioned at the edge portion but at the central portion of the printed pattern.

### Experimental Example 5

### Verification of Control Probability of Width of Organic Semiconductor Thin Film in Multi-Layered Thin Films

### Experimental Example 5

### Observation of Change in Width of Organic Semiconductor Thin Film According to Change in Weight Ratio in Blend Solution

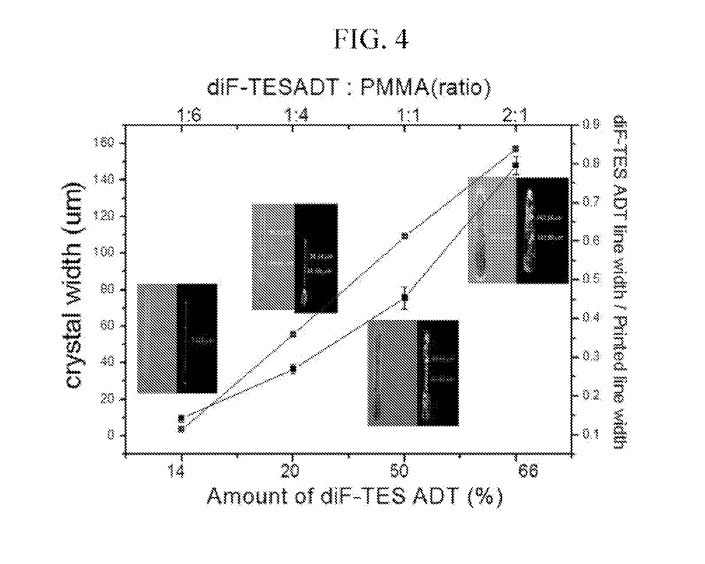

FIG. 4 shows a width of each crystalline organic semiconductor thin film in the multi-layered thin films manufactured in Examples 1 to 4.

As illustrated in FIG. 4, it can be verified that the width of the organic semiconductor thin film in the multi-layered thin films is decreased as the weight ratio of the organic semiconductor to the insulating polymer in the blend solution is decreased.

That is, it can be inferred that the width of the organic semiconductor thin film in the manufactured multi-layered thin films may be decreased as the weight ratio of the organic semiconductor to the insulating polymer in the blend solution is decreased. Further, it can be seen that the width of the organic semiconductor may be controlled by using this.

### Experimental Example 6

### Verification of Control Probability of Thickness of Insulating Polymer Thin Film in Multi-Layered Thin Films

### Experimental Example 6

### Observation of Change in Thickness of Insulating Polymer Thin Film According to Change of Total Concentration in Blend Solution

FIG. 6 illustrates a change in thickness and a surface profile of an insulating polymer thin film according to a change in total concentration of an organic semiconductor and an insulating polymer in a blend solution, in the multi-layered thin film pattern manufactured according to Examples 3 and 5 to 8.

In FIG. 6, it can be verified that the thickness of the insulating polymer thin film is increased as the total concentration of the organic semiconductor and the insulating polymer in the blend solution is increased.

Accordingly, it can be seen that the thickness of the insulating polymer thin film in the multi-layered thin films may be effectively controlled by controlling the total concentration of the organic semiconductor and the insulating polymer in the blend solution.

### Experimental Example 7

### Verification of Control Probability of Width of Printed Pattern, Width of Organic Semiconductor Thin Film, and Thickness of the Insulating Polymer Thin Film in Multi-Layered Thin Films

### Experimental Example 7

### Observation of Surface Profile and Change in Thickness of Bottom Insulating Polymer Thin Film According to Change in Printing Speed of Multi-Layered Thin Films

FIG. 7 is a diagram showing a surface profile and a change in thickness of the bottom insulating polymer thin film according to a change in printing speed, in a printing process for forming a pattern of the multi-layered thin films according to the exemplary embodiment of the present invention.

According to FIG. 7, it can be verified that the width of the printed pattern is decreased, and accordingly, the width of the organic semiconductor thin film is decreased as the speed of printing the multi-layered thin film pattern is increased. Meanwhile, it can be verified that the thickness of the insulating polymer thin film is increased.

Accordingly, it can be seen that the width of the printed pattern, the width of the organic semiconductor thin film, and the thickness of the insulating polymer thin film may be effectively controlled by controlling the printing speed of the multi-layered thin film pattern.

### Experimental Examples 8 and 9

### Manufacturing of Organic Thin Film Transistor and Observation of Element Characteristic

### Experimental Example 8

### Manufacturing of Organic Thin Film Transistor

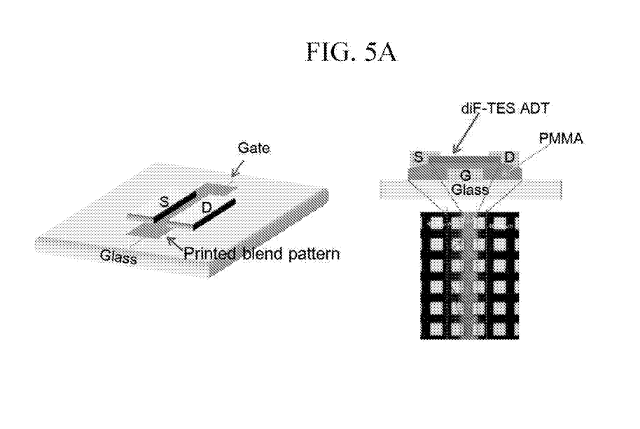

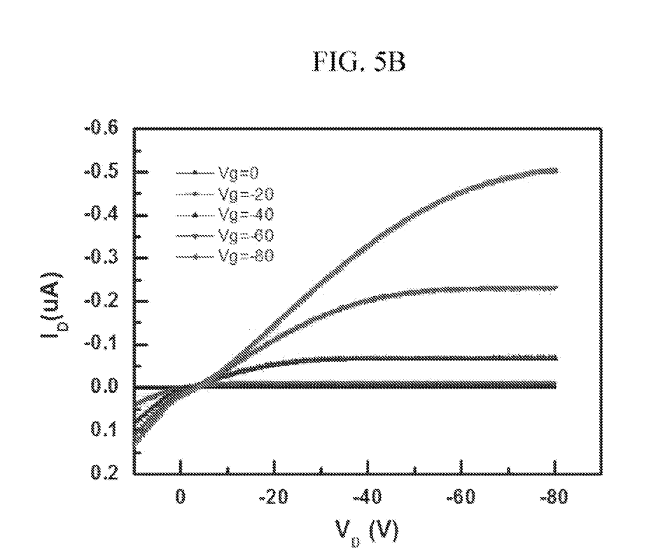

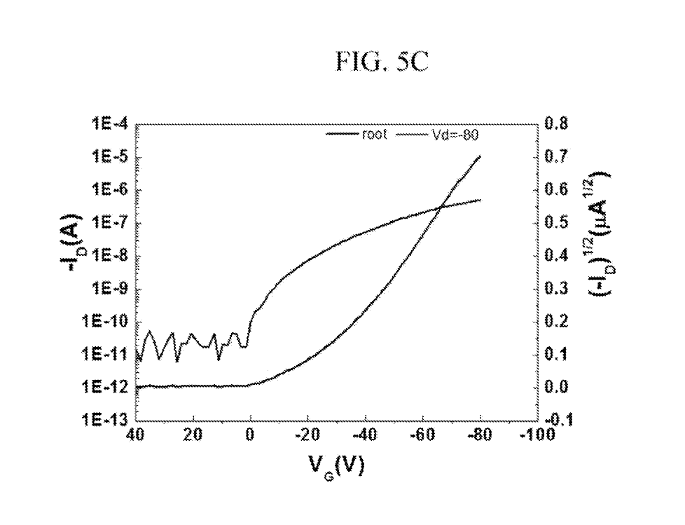

The organic thin film transistor was manufactured by depositing a gate electrode on a glass substrate (Marienfeld, microscope slides) by using a mask, printing a blend solution on a gate line by using a microfluidic dispenser in the same manner as Example 2, and then depositing a source electrode and a drain electrode on the printed pattern. FIG. 5A schematically illustrates an element structure of the organic thin film transistor manufactured as described above.

### Experimental Example 9

### Observation of Element Characteristic of Manufactured Organic Thin Film Transistor

The thicknesses of the organic semiconductor thin film and the insulating polymer thin film of the organic thin film transistor manufactured in Example 2 were 100 nm and 640 nm, respectively. The organic semiconductor thin film had the width of 100 μm of the entire width of 200 μm at the central portion of the printed pattern. Further, it can be verified that a channel length of the element is 30 μm and a channel width is 50 μm.

FIGS. 5B and 5C illustrate output and transfer characteristics of the organic thin film transistor, and show an excellent characteristic in field effect mobility.

The present invention is not limited to the exemplary embodiments, but can be manufactured by various different forms, and those skilled in the art can understand that the present invention can be implemented by different detailed forms without changing the technical spirit or necessary features of the present invention. Therefore, it should be understood that the exemplary embodiments described above will be exemplified in all respects and not limited.

What is claimed is:

1. A method of manufacturing multi-layered thin films, comprising:
preparing a substrate;
printing a blend solution including an organic semiconductor, an insulating polymer, and a solvent on the substrate; and
simultaneously forming an insulating polymer thin film and an organic semiconductor thin film on the insulating polymer thin film by using a vertical phase separation phenomenon of the organic semiconductor and the insulating polymer,
wherein according to contents of the organic semiconductor and the insulating polymer in the blend solution and/or a printing speed of the blend solution, a width of the multi-layered thin film pattern, a width of the organic semiconductor thin film, and a thickness of the insulating polymer thin film are controlled.

2. The method of claim 1, wherein
the insulating polymer is an amorphous polymer.

3. The method of claim 1, wherein
the insulating polymer is a polyacrylate-based polymer, a polyimide-based polymer, a polyphenol-based polymer, a polyvinyl alcohol-based polymer, or a combination thereof.

4. The method of claim 1, wherein
the organic semiconductor is a thiophene-based compound, a thiazine-based compound, a polyacene-based derivative, a polyaniline-based compound, a polyacetylene-based compound, or a combination thereof.

5. The method of claim 1, wherein
the solvent is an organic chlorine-based compound, an organic fluorine-based compound, a hydrocarbon-based compound, an alcohol-based compound, a benzene-based compound, or a combination thereof.

6. The method of claim 1, wherein
the solvent is 1,2,4-trichlorobenzene (TCB).

7. The method of claim 1, wherein
the content of the organic semiconductor and the insulating polymer in the blend solution is a weight ratio of the organic semiconductor to the insulating polymer of 2:1 to 1:8.

8. The method of claim 1, wherein
the content of the organic semiconductor and the insulating polymer in the blend solution is a weight ratio of the organic semiconductor to the insulating polymer of 1:1 to 1:6.

9. The method of claim 1, wherein
a width of the organic semiconductor thin film is 1 to 200 μm.

10. The method of claim 1, wherein
a width of the organic semiconductor thin film is 1 to 10 μm.

11. The method of claim 1, wherein
the content of the organic semiconductor and the insulating polymer in the blend solution is 1 to 15 wt %.

12. The method of claim 1, wherein
the thickness of the insulating polymer thin film is 10 to 1000 nm.

13. The method of claim 1, wherein
the thickness of the insulating polymer thin film is 50 to 600 nm.

14. The method of claim 1, wherein
the organic semiconductor thin film is positioned at a center of the printed pattern.

15. The method of claim 1, wherein
the substrate has larger surface energy than surface energy of the insulating polymer.

16. The method of claim 1, wherein
the substrate is a silicon substrate.

17. The method of claim 1, wherein
the substrate is a polymer substrate.

18. The method of claim 1, wherein
in the printing of the blending solution including the organic semiconductor, the insulating polymer, and the solvent on the substrate,
the printing method is at least one method of inkjet printing, roll to roll printing, or screen printing.

19. The method of claim 1, wherein
in the printing of the blending solution including the organic semiconductor, the insulating polymer, and the solvent on the substrate,
the printing speed is 10 to 2000 μm/s.

20. The method of claim 1, wherein
in the printing of the blending solution including the organic semiconductor, the insulating polymer, and the solvent on the substrate,
the printing method uses a microfluidic dispenser.

21. Multi-layered thin films manufactured according to claim 1, wherein a blend solution including an organic semiconductor, an insulating polymer, and a solvent is printed to form an insulating polymer layer and an organic semiconductor layer on the insulating polymer layer.

22. A method of manufacturing an organic thin film transistor, comprising:
preparing a substrate;
preparing a gate electrode on the substrate;
printing a blend solution including an organic semiconductor, an insulating polymer, and a solvent according to claim 1; and
forming a source electrode and a drain electrode on the printed pattern.

23. The method of claim 22, wherein
in the forming of the source electrode and the drain electrode on the printed pattern,
the source electrode and the drain electrode are formed by printing.

24. An organic thin film transistor manufactured according to claim 23, comprising:
a substrate to which a gate electrode is connected;
a first dielectric layer formed on the substrate;
a second dielectric layer formed on the first dielectric layer;
an organic semiconductor thin film formed on the second dielectric layer; and
source and drain electrodes connected to the organic semiconductor thin film.
